(19) United States
(12) Patent Application Publication
(10) Pub. No.: US 2014/0011306 A1
(43) Pub. Date: Jan. 9, 2014

(54) INSPECTING METHOD AND INSPECTING EQUIPMENT

(71) Applicant: MACRONIX INTERNATIONAL CO., LTD., Hsinchu (TW)

(72) Inventors: Kai-Wen TU, Hsinchu (TW); Jen-Hung WANG, Taichung City (TW); Chung-Hsien CHOU, Hsinchu (TW); Wen-Sen PAN, Hsinchu City (TW)

(73) Assignee: MACRONIX INTERNATIONAL CO., LTD., Hsinchu (TW)

(21) Appl. No.: 14/027,264

(22) Filed: Sep. 16, 2013

Related U.S. Application Data
(63) Continuation-in-part of application No. 12/174,063, filed on Jul. 16, 2008.

(51) Int. Cl. H01L 21/66; G06F 17/00

(52) U.S. Cl. CPC H01L 22/12; G06F 17/00
USPC 438/14; 702/83

(57) ABSTRACT

An inspecting method and an inspecting equipment including a dividing unit, a determining unit, a transferring unit and an inspecting unit for inspecting a disk are provided. The inspecting method includes the following steps. First, a plane is divided into several zones with equal area. Next, several measuring locations are determined within these zones. Next, these measuring locations are transferred into several sets of measuring locations corresponding to the disk through a coordinate transfer. Then, the disk is inspected according to these sets of measuring locations.

### CROSS-REFERENCE TO RELATED APPLICATION

This application is a continuation in part of U.S. application Ser. No. 12/174,063, filed Jul. 16, 2008.

### BACKGROUND OF THE INVENTION

1. Field of the Invention

The invention relates in general to an inspecting method and an inspecting equipment, and more particularly to an inspecting method and an inspecting equipment for inspecting a disk.

2. Description of the Related Art

With the coming of the digital electronic age, semiconductor chips have been widely applied to various electronic devices, and the demand for semiconductor chips are rapidly growing in the market. Therefore, effective methods for manufacturing large amount of semiconductor chips with low cost have been continuously developed. Typically, the method of manufacturing the semiconductor chip includes an inspecting procedure for inspecting wafer surfaces by an inspecting equipment during the manufacturing process, so that the condition of the manufacturing process can be revealed according to the inspecting result. The abnormal quality of the manufacturing process can be reflected during the manufacturing process in order to monitor the manufacturing quality. Therefore, the determination of the locations of measuring points on the wafer surface to be inspected directly influences the inspecting result and precision.

FIG. 1 is a schematic illustration showing the distribution of measuring points on a conventional wafer surface. In order to facilitate the determination of the locations of several measuring points 13 on a wafer surface 100, the measuring points 13 are usually arranged along several concentric circles on the wafer surface 100 and are usually symmetrically distributed. In addition, when several wafer surfaces 100 are inspected, the arrangements of the measuring points 13 on the wafer surfaces 100 to be inspected are the same.

However, due to the reasons that the measuring points 13 are arranged along the concentric circles and the measuring locations of the wafers are the same, the measuring result only can reflect the conditions near the concentric circles, but cannot completely represent the condition of the overall manufacturing processes. Thus, the manufacturing quality cannot be effectively monitored accordingly. In addition, the number and the locations of the measuring points 13 cannot effectively match with the inspecting sensitivity to be reached. That is, the conventional inspecting method and equipment cannot effectively change the inspecting sensitivity by correspondingly adjusting the locations and the number of the measuring points 13, and the application adaptability of the inspecting method and equipment is greatly limited.

### SUMMARY OF THE INVENTION

The invention is directed to an inspecting method and an inspecting equipment for a disk. The inspecting method divides the surface of the disk into several measuring zones having equal area, and determines several measuring locations within these measuring zones so that the measuring locations can cover different radii and different central angles on the surface of the disk, thereby enhancing the precision of inspecting the disk.

According to the present invention, an inspecting method for a disk is provided. First, a plane is divided into several zones with equal area. Next, several measuring locations are determined within the zones. Then, the measuring locations are transferred into several sets of measuring locations corresponding to the disk through a coordinate transfer. Afterwards, the disk is inspected according to the sets of measuring locations.

According to the present invention, another inspecting method for a disk is provided. First, several sets of measuring locations from several zones by dividing a plane according to a radius squared parameter and a central angle parameter are provided. Then, several ones of the sets of measuring locations are extracted by way of sampling without replacement to constitute a collection of sets of measuring locations. Then, the disk is inspected according to the extracted collection of sets of measuring locations.

According to the present invention, an inspecting equipment for a disk is further provided. The inspecting equipment includes a dividing unit, a determining unit, a transferring unit and an inspecting unit. The dividing unit is used for dividing a plane into a plurality of zones with equal area. The determining unit is used for determining a plurality of measuring locations within the plurality of zones. The transferring unit is used for transferring the plurality of measuring locations into a plurality of sets of measuring locations corresponding to the disk through a coordinate transfer. The inspecting unit is used for inspecting the disk according to the plurality of sets of measuring locations.

According to the present invention, another inspecting equipment for a disk is further provided. The inspecting equipment includes an extracting unit and an inspecting unit. The extracting unit is used for extracting several ones of several sets of measuring locations from several zones by dividing a plane according to a radius squared parameter and a central angle parameter by way of sampling without replacement, such that a collection of sets of measuring locations is constituted. The inspecting unit is used for inspecting the disk according to the extracted collection of sets of measuring locations.

The invention will become apparent from the following detailed description of the preferred but non-limiting embodiment. The following description is made with reference to the accompanying drawings.

### BRIEF DESCRIPTION OF THE DRAWINGS

FIG. 1 (Prior Art) is a schematic illustration showing the distribution of measuring points on a conventional wafer surface.

FIG. 2A is a function block diagram of an inspecting equipment according to a preferred embodiment of the invention;

FIG. 2B is a block diagram of the inspecting equipment, illustrating the implementation of the functional units shows in FIG. 2A at least partially in physical hardware;

FIG. 3 is a flow chart showing an inspecting method according to a preferred embodiment of the invention.

FIG. 4 is a plane coordinate chart showing radius squared parameters and central angle parameters.

FIG. 5 is a schematic illustration showing a disk divided into several measuring zones having equal area.

FIG. 6 is a profile chart showing differences between the averages of inspecting values of each wafer surface and the actual averages.

FIG. 7 is a profile chart showing differences between the standard deviations of inspecting values of each wafer surface and the actual standard deviations.

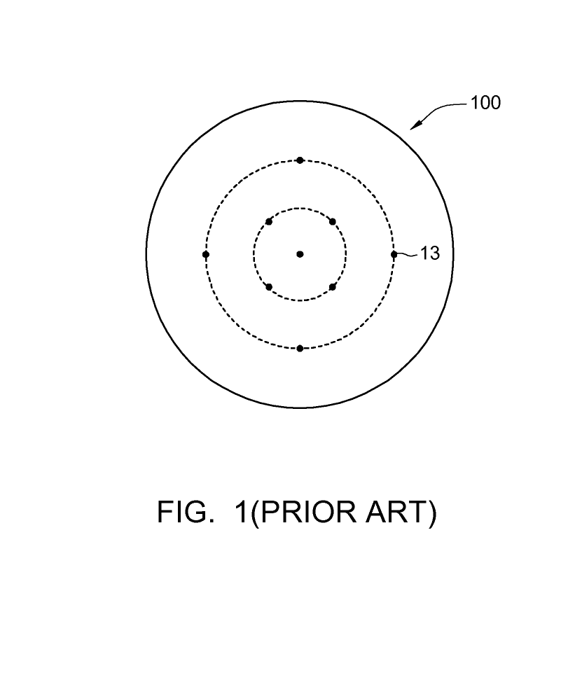

### DETAILED DESCRIPTION OF THE INVENTION

The inspecting method and inspecting equipment according to the preferred embodiment of the invention is used for inspecting a disk. In the inspecting method, the surface of the disk is divided into several measuring zones having equal area, several measuring locations are determined, and then these measuring locations are transferred into a set of measuring locations corresponding to the disk according to a coordinate transfer. Illustrations will be made by taking a non-limitative embodiment as an example. In addition, non-essential elements are omitted in the drawings according to the embodiment of the invention in order to clearly show the technological features of the invention.

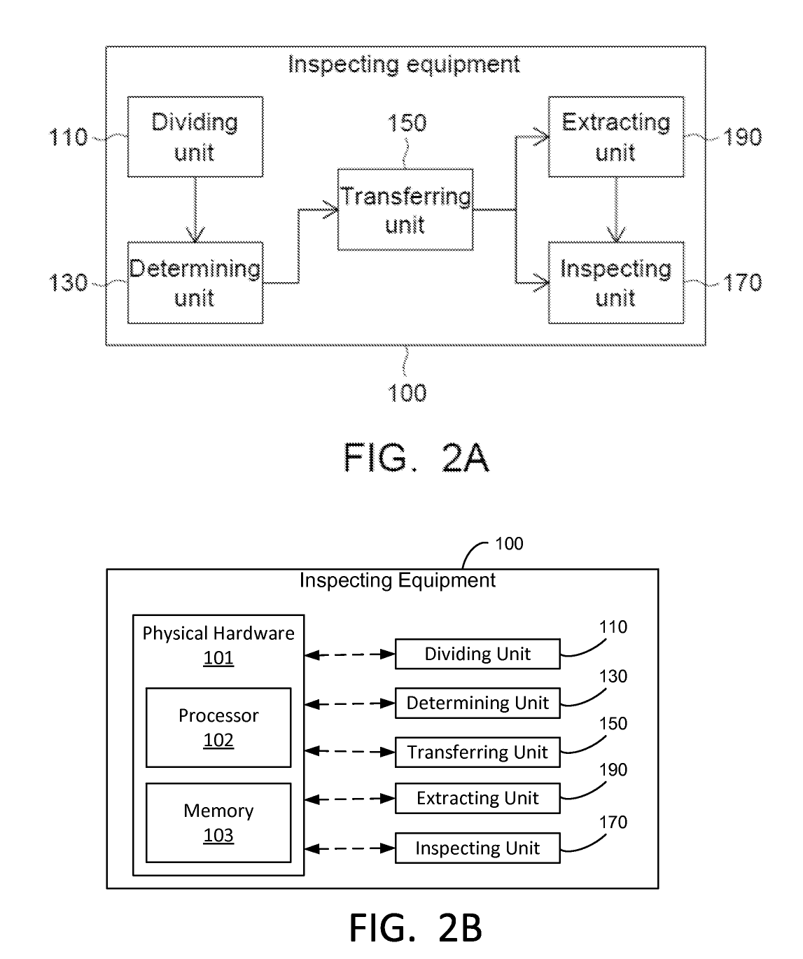

Referring to FIG. 2A, a function block diagram of an inspecting equipment according to a preferred embodiment of the invention is illustrated. The inspecting equipment 100 for inspecting a disk includes a dividing unit 110, a determining unit 130, a transferring unit 150 and an inspecting unit 170. The dividing unit 110 is used for dividing a plane into a plurality of zones with equal area. The plane is preferably a coordinate plane. The determining unit 130 is used for determine several measuring locations within these zones. The transferring unit 150 is used for transferring these measuring locations into several sets of measuring locations corresponding to the disk through a coordinate transfer. The inspecting unit 170 is used for inspecting the disk according to these sets of measuring locations.

FIG. 2B shows a block diagram illustrating the implementation of the functional blocks of FIG. 2A. As illustrated, these blocks are implemented using physical hardware. Persons skilled in the art will appreciate the implementation of these blocks, based on the description herein. For example, as illustrated, the inspecting equipment includes physical hardware 101. A portion of this physical hardware includes a processor 102 and memory 103. As is known semiconductor devices are fabricated to include integrated circuits (e.g., unique interconnections and configurations of transistors) which carry out the functions of the functional blocks illustrated in FIG. 2A.

Other physical hardware may also be included. For example, the transferring unit 150 includes a physical carriage or other mechanism capable of moving/transferring a wafer. In addition, electronic circuitry is also included in conjunction with such a carriage to control the carriage and transfer of the wafers. The precise physical structure of the carriage/transferring unit need not be further specified herein, as it will be appreciated by persons skilled in the art.

FIG. 2B illustrates dashed lines between each of the functional units (i.e., the dividing unit 110, the determining unit 130, the transferring unit 150, the inspecting unit 170, and the extracting unit 190). These dashed line illustrate the concept that the functional units are implemented at least partially in physical hardware, including the processor 102 and memory 103.

As indicated above, the functional unit will be implemented at least partially in integrated circuitry, which comprises a unique configuration of transistors. Persons skilled in the art will appreciate that the unique interconnections will be created using tool like an RTL (register transfer language) compiler, which is a tool that allows engineers to specify a circuit design based on Boolean or other functionality, and the compiler generates the specification for the integrated circuitry based on the specified functionality.

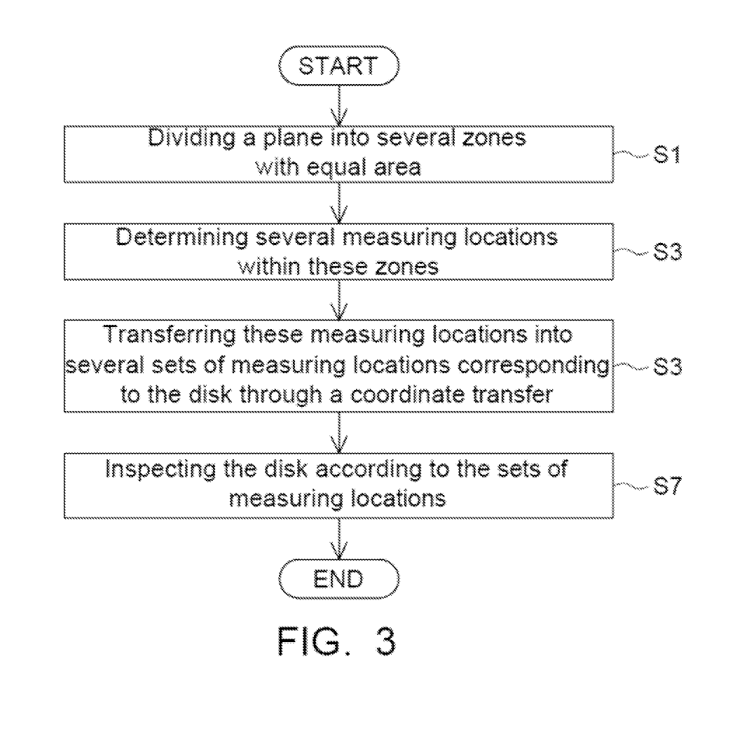

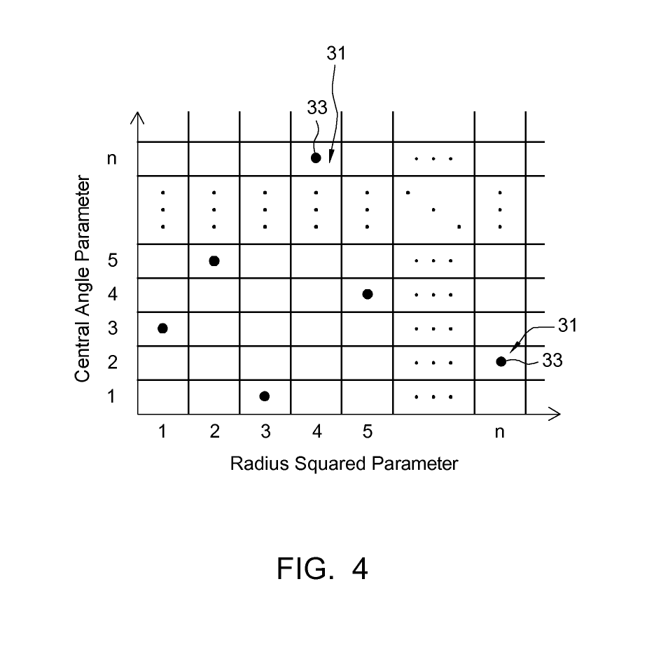

The inspecting method for inspecting the disk is elaborated in the following description with reference to FIG. 3, which is a flow chart showing an inspecting method according to a preferred embodiment of the invention. The inspecting method of the embodiment includes the following steps. First, in step S1, a plane is divided into several plane zones with equal area. In the present embodiment, the plane is the coordinate plane that constituted by a radius squared parameter and a central angle parameter, and the plane is divided by the dividing unit 110 according to the radius squared parameter and the central angle parameter, so as to correspondingly divide the disk into several measuring zones having equal area. In practice, the inspecting method may include the step of setting an inspecting sensitivity before the step S1. The dividing unit 110 is used for dividing the plane in accordance with the inspecting sensitivity. The number of partitions of the disk is determined according to the inspecting sensitivity. FIG. 4 is a plane coordinate chart showing radius squared parameters and central angle parameters. As shown in FIG. 4, in the step S1 of the inspecting method of the present embodiment, the radius squared parameter is equally divided into n equal sections and the central angle parameter is equally divided into n equal sections according to the inspecting sensitivity, and n is a positive integer. Therefore, the coordinate plane constituted by the radius squared parameter and the central angle parameter may be divided into n² zones 31. In addition, the n² zones 31 are transferred into several measuring zones with equal area on the surfaces of the disk by a polar coordinate transfer for example.

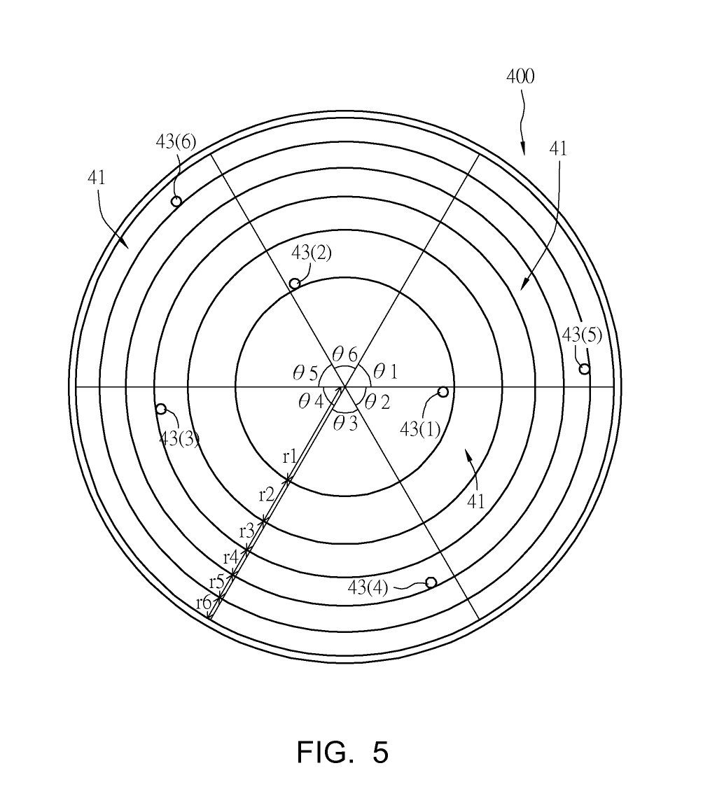

In the present embodiment, the radius squared parameter is exemplified by equally dividing into 6 equal sections, and the central angle parameter is exemplified by equally dividing into 6 equal sections. FIG. 5 is a schematic illustration showing a disk divided into several measuring zones having equal area. After the polar coordinate transfer, a disk 400 is divided into 6 sections r1˜r6 in a radial direction, and a central angle of the disk 400 is divided into 6 angles θ1˜θ6, so that the disk 400 is divided into 36 measuring zones 41 having equal area. On the other hand, the radius squared parameter is equally divided into 6 equal sections, and the central angle parameter is equally divided into 6 equal sections in this non-limitative exemplified embodiment. However, the dividing numbers for the parameters are not limited thereto. The inspecting method of the present embodiment may divide the two parameters individually into fewer or more than 6 equal sections according to different settings of the inspecting sensitivity. For example, the parameters may be individually divided into 5 equal sections, 7 equal sections or 9 equal sections.

Next, the inspecting method of the present embodiment performs step S3, several measuring locations 33 are determined within these zones 31. In the present embodiment, several measuring locations 33 are determined by the determining unit 130 within these zones 31 preferably through the space-filling design methodology of design of experiment (DOE). The measuring locations 33 individually correspond to different sections of the radius squared parameter and different sections of the central angle parameter, so that the measuring locations 33 are correspondingly and individually located in different zones 31, as shown in FIG. 4. In the present embodiment, the central angle parameter is the vertical coordinate axis of the plane, and the radius squared parameter is the horizontal coordinate axis of the plane, as shown in FIG. 4. However, the central angle parameter and the radius squared parameter can also respectively be the horizontal and the vertical coordinate axis of the plane, so as to acquire measuring locations 33 of different distribution without more locations added.

Then, as shown in step S5, these measuring locations 33 are transferred into several sets of measuring locations corresponding to the disk 400 through a coordinate transfer. In the present embodiment, the transferring of the measuring locations 33 are performed by the transferring unit 150. Each set of measuring locations preferably includes, for example, six measuring points 43(1)˜43(6) on the disk 400. Because the measuring locations 33 are individually located in different zones 31, the measuring points 43(1)˜43(6) are correspondingly and individually located in different measuring zones 41 of the disk 400. In the present embodiment, these measuring locations 33 are transferred into the measuring points 43(1)˜43(6) on the disk 400 by a polar coordinate transfer for example. More specifically, the method of transferring the measuring locations 33 according to the present embodiment includes the following steps for example. First, an initial central angle is set on the disk 400. Next, these measuring locations 33 are sequentially transferred from the initial central angle into the sets of measuring locations on the wafer surface 400 by the transferring unit 150 of the inspecting equipment 100.

Then, the inspecting method according to the present embodiment performs step S7, the disk 400 is inspected according to the sets of measuring locations. In the present embodiment, the inspection is performed by the inspecting unit 170 of the inspecting equipment 100.

On the other hand, the inspecting equipment 100 of the present embodiment further includes an extracting unit 190. In the present embodiment, the steps S3 and S5 may be repeated several times until the number of these sets of measuring locations are obtained. And then, several ones of these sets of measuring locations are extracted by the extracting unit 190 by way of sampling without replacement in order to constitute a collection of sets of measuring locations, and the disk are inspected by the inspecting unit 170 according to the extracted collection of sets of measuring locations. Because several measuring locations are determined by the space-filling design methodology of DOE each time when the step S3 is performed, the sets of measuring locations accordingly transferred from the step S5 may be different from one another. Furthermore, each time when the step S5 is performed, the initial central angle may be optionally changed, so that the sets of measuring locations that are accordingly transferred are different from one another. Consequently, the disk can be individually inspected according to different sets of measuring locations.

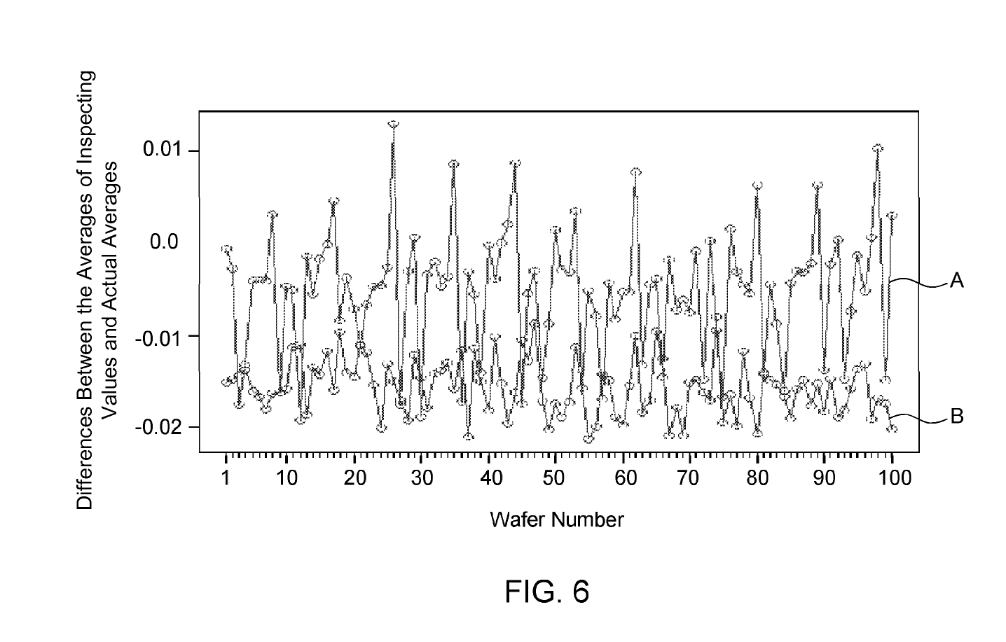

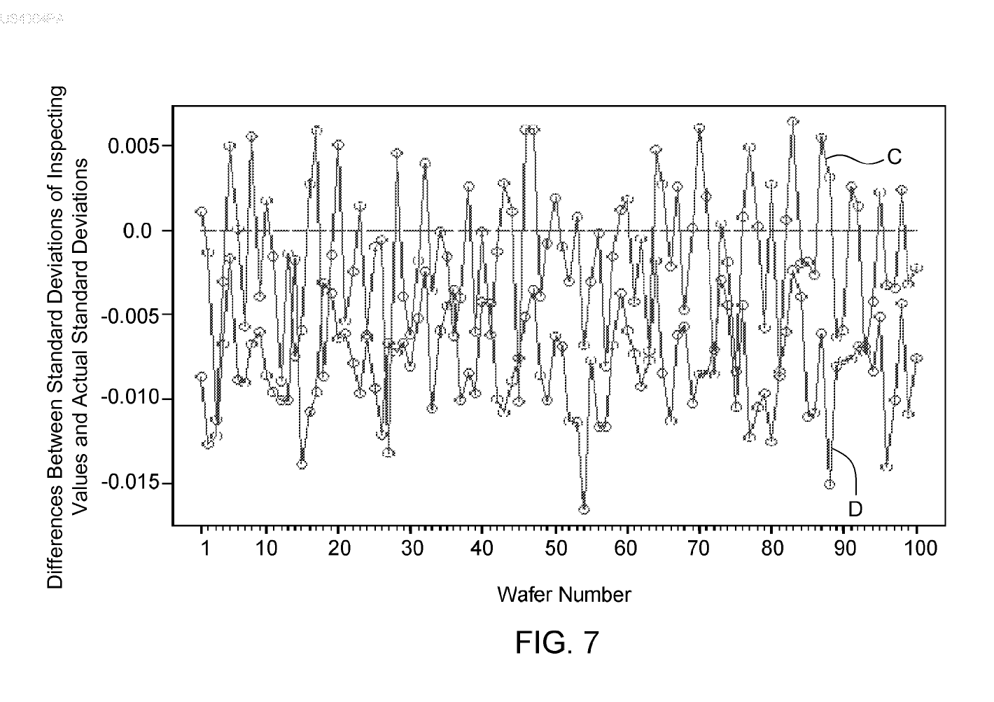

The illustrations of the present embodiment will be made according to the simulated inspecting results. The applicable example of the disk includes a wafer. In the simulating process, 100 wafers, which are numbered from 1 to 100 and have wafer mapping data of manufacturing defect patterns, are generated randomly by a statistical method to serve as a calculating reference for the actual measuring values. After that, nine measuring points arranged symmetrically on concentric circles of each wafer surface are obtained according to the conventional inspecting method, and the inspection process is performed to obtain the measuring values. On the other hand, nine measuring points on each wafer surface are obtained according to the inspecting method of the present embodiment, and the inspection process is performed to obtain the measuring values. Thereafter, one profile chart is plotted according to the differences between the averages of the measuring values of the measuring points on each wafer surface and the averages of the actual measuring values, and another profile chart is plotted according to the differences between the standard deviations of the measuring values of the measuring points on each wafer surface and the standard deviations of the actual measuring values. FIG. 6 is a profile chart showing differences between the averages of inspecting values of each wafer surface and the actual averages. Curve A represents the inspecting values obtained according to the inspecting method of the present embodiment, while curve B represents the inspecting values obtained according to the conventional inspecting method. As shown in FIG. 6, comparing with the curve B, the curve A is substantially closer to the actual averages. FIG. 7 is a profile chart showing differences between the standard deviations of inspecting values of each wafer surface and the actual standard deviations. Curve C represents the inspecting values obtained according to the inspecting method of the present embodiment, while curve D represents the inspecting values obtained according to the conventional inspecting method. As shown in FIG. 7, comparing with the curve D, the curve C is substantially closer to the actual standard deviations. According to the simulated experimental inspecting result mentioned hereinabove, the inspecting values of the invention are closer to the actual inspecting values because the averages and the standard deviations of the inspecting values obtained according to the inspecting method of the present embodiment are closer to those obtained according to the conventional inspecting method. Therefore, the inspecting method according to the present embodiment can further show the actual conditions of the manufacturing process, and effectively enhance the inspecting precision.

According to the above-described inspecting method and inspecting equipment of the preferred embodiment of the invention, the disk, exemplified by a wafer, is divided into several measuring zones having equal area, and the measuring locations are transferred into several sets of measuring locations corresponding to the surface of the disk by the coordinate transfer. After obtaining these sets of measuring locations, several ones of these sets of measuring locations are extracted by way of sampling without replacement to constitute a collection of sets of measuring locations. Then, the disk can be inspected according to the collection of sets of measuring locations. In the present embodiment, the number of measuring points on the disk may be determined according to the predetermined inspecting sensitivity, so that good inspecting adaptability can be obtained. Furthermore, the sets of measuring locations of the disk are different from one another, and each set of measuring locations covers different sections of radius and different sections of central angle. Therefore, the inspecting precision can be enhanced, and the measuring result can reflect actual condition of the manufacturing process. In addition, the inspecting equipment may be applied to an inline inspecting system, making the inspecting system can automatically obtain the inspecting points on the disk. Hence, the real-time quality inspection of the disk may be performed and the abnormal disk quality can be detected in time, and the inspecting efficiency can be enhanced.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An inspecting method executed by a processor in inspecting equipment for inspecting a disk to ascertain a condition in a manufacturing process, the method comprising:
dividing a plane of the disk into a plurality of zones with equal area using a dividing unit of the inspecting equipment;
determining a plurality of measuring locations within the plurality of zones of the disk using a determining unit of the inspecting equipment, wherein each of the plurality of measuring locations is individually located in different zone of the plurality of zones from the remaining plurality of measuring locations;
transferring the plurality of measuring locations into a plurality of sets of measuring locations corresponding to the disk through a coordinate transfer using a transferring unit of the inspecting equipment; and
inspecting positions of the disk corresponding to the plurality of sets of measuring locations using an inspecting unit of the inspecting equipment.

2. The method according to claim 1, wherein in the step of dividing the plane, the plane is divided into the plurality of zones by a radius squared parameter and a central angle parameter.

3. The method according to claim 2, wherein in the step of dividing the plane, the radius squared parameter and the central angle parameter are respectively a vertical coordinate axis and a horizontal coordinate axis of the plane.

4. The method according to claim 2, wherein in the step of dividing the plane, the radius squared parameter and the central angle parameter are respectively a horizontal coordinate axis and a vertical coordinate axis of the plane.

5. The method according to claim 1, wherein in the step of determining the plurality of measuring locations, the plurality of measuring locations is determined by space filling design methodology of design of experiment (DOE).

6. The method according to claim 1, wherein in the step of determining the plurality of measuring locations, the plurality of measuring locations respectively correspond to different zones.

7. The method according to claim 1, wherein before the step of dividing the plane, the method further comprising:
setting an inspecting sensitivity to determine the number of the zones.

8. The method according to claim 7, wherein in the step of dividing the plane, the plane is divided into the plurality of zones by a radius squared parameter and a central angle parameter, and the radius squared parameter is equally divided into n equal sections and the central angle parameter is equally divided into n equal sections according to the inspecting sensitivity, wherein n is a positive integer.

9. The method according to claim 8, wherein in the step of determining the plurality of measuring locations, the measuring locations respectively correspond to different sections of the radius squared parameter and different sections of the central angle parameter, so that the measuring locations are respectively and correspondingly located in different zones.

10. The method according to claim 1, wherein the step of transferring the measuring locations comprises:
setting an initial central angle;
sequentially transferring the measuring locations from the initial central angle into the plurality of sets of measuring locations using the transferring unit.

11. The method according to claim 1, further comprising:
repeating the step of determining the plurality of measuring locations and the step of transferring the measuring locations until the plurality of the sets of measuring locations is obtained; and
extracting several ones of the sets of measuring locations by way of sampling without replacement to constitute a collection of sets of measuring locations using an extracting unit of the inspecting equipment, and inspecting positions of the disk corresponding to the extracted collection of sets of measuring locations using the inspecting unit of the inspecting equipment.

12. The method according to claim 1, wherein the disk comprises a wafer.

13. An inspecting method performed by circuitry in inspecting equipment for inspecting a disk to ascertain a condition in a manufacturing process, the method comprising:
providing a plurality of sets of measuring locations from a plurality of zones by dividing a plane of the disk using a dividing unit of the inspecting equipment according to a radius squared parameter and a central angle parameter, wherein each of the plurality of measuring locations is individually located in different zone of the plurality of zones from the remaining plurality of measuring locations;
extracting several ones of the sets of measuring locations using an extracting unit of the inspecting equipment by way of sampling without replacement to constitute a collection of sets of measuring locations; and
inspecting positions of the disk corresponding to the extracted collection of sets of measuring locations using an inspecting unit of the inspecting equipment.

14. The method according to claim 13, wherein in the step of providing the plurality of sets of measuring locations, the radius squared parameter and the central angle parameter are respectively a vertical coordinate axis and a horizontal coordinate axis of the plane.

15. The method according to claim 13, wherein in the step of providing the plurality of sets of measuring locations, the radius squared parameter and the central angle parameter are respectively a horizontal coordinate axis and a vertical coordinate axis of the plane.

16. The method according to claim 13, wherein the disk comprises a wafer.

17. An inspecting equipment for a disk, comprising:
a dividing unit comprising logic for dividing a plane of the disk into a plurality of zones with equal area;
a determining unit comprising logic for determine a plurality of measuring locations within the plurality of zones of the disk, wherein each of the plurality of measuring locations is individually located in different zone of the plurality of zones from the remaining plurality of measuring locations;
a transferring unit comprising logic for transferring the plurality of measuring locations into a plurality of sets of measuring locations corresponding to the disk through a coordinate transfer; and
an inspecting unit comprising logic for inspecting positions of the disk corresponding to the plurality of sets of measuring locations.

18. The inspecting equipment according to claim 17, wherein the dividing unit is used for dividing the plane into the plurality of zones by a radius squared parameter and a central angle parameter.

19. The inspecting equipment according to claim 18, wherein the radius squared parameter and the central angle parameter are respectively a vertical coordinate axis and a horizontal coordinate axis of the plane.

20. The inspecting equipment according to claim 18, wherein the radius squared parameter and the central angle parameter are respectively a horizontal coordinate axis and a vertical coordinate axis of the plane.

21. The inspecting equipment according to claim 17, wherein the determining unit is used for determining the plurality of measuring locations by space design methodology of design of experiment.

22. The inspecting equipment according to claim 17, wherein the plurality of measuring locations respectively correspond to different zones.

23. The inspecting equipment according to claim 17, wherein the dividing unit is used for dividing the plane in accordance with an inspecting sensitivity so as to determine the number of the zones.

24. The inspecting equipment according to claim 23, wherein the dividing unit is used for dividing the plane into the plurality of zones by a radius squared parameter and a central angle parameter, and the dividing unit is further used for equally dividing the radius squared parameter into n equal sections and the central angle parameter into n equal sections according the inspecting sensitivity, wherein n is a positive integer.

25. The inspecting equipment according to claim 24, wherein the measuring locations respectively correspond to different sections of the radius squared parameter and different sections of the central angle parameter, so that the measuring locations are respectively and correspondingly located in different zones.

26. The inspecting equipment according to claim 17, wherein the transferring unit is used for sequentially transferring the measuring locations into the plurality of sets of measuring locations from an initial central angle.

27. The inspecting equipment according to claim 17 further comprising:
an extracting unit for extracting several ones of the sets of measuring locations by way of sampling without replacement, such that a collection of sets of measuring locations is constituted;
wherein the inspecting unit is used for inspecting positions of the disk corresponding to the extracted collection of sets of measuring locations.

28. An inspecting equipment for a disk, comprising:
an extracting unit comprising logic for extracting several ones of a plurality of sets of measuring locations from a plurality of zones by dividing a plane of the disk according to a radius squared parameter and a central angle parameter by way of sampling without replacement, such that a collection of sets of measuring locations is constituted, wherein each of the plurality of measuring locations is individually located in different zone of the plurality of zones from the remaining plurality of measuring locations; and
an inspecting unit comprising logic for inspecting positions of the disk corresponding to the extracted collection of sets of measuring locations.

29. The inspecting equipment according to claim 28, wherein the radius squared parameter and the central angle parameter are respectively a vertical coordinate axis and a horizontal coordinate axis of the plane.

30. The inspecting equipment according to claim 28, wherein the radius squared parameter and the central angle parameter are respectively a horizontal coordinate axis and a vertical coordinate axis of the plane.
